(19) United States
(12) Patent Application Publication
(10) Pub. No.: US 2013/0063195 A1
(43) Pub. Date: Mar. 14, 2013

(54) DIGITAL INPUT BUFFER

(71) Applicant: Tom Youssef, Frisco, TX (US)

(72) Inventor: Tom Youssef, Frisco, TX (US)

(73) Assignee: STMICROELECTRONICS, INC., Coppell, TX (US)

(21) Appl. No.: 13/467,256

(22) Filed: May 9, 2012

Related U.S. Application Data
(60) Provisional application No. 61/532,197, filed on Sep. 8, 2011.

(51) Int. Cl. H03K 3/027

(52) U.S. Cl. 327/225

(57) ABSTRACT

A digital input buffer and method. The input buffer includes a voltage regulator configured for operating in weak inversion and outputting a regulated potential, an inverter having as its power source the regulated potential and configured for receiving an input signal, a first latch having its input coupled to the inverter input, and a second latch having its input coupled to the inverter's output, having its output coupled to the first latch's enable input, and having its enable input coupled to the first latch's output. A first latch output signal from the first latch output and a second latch output signal from the second latch output enable switching the first latch output signal to the complement of the input signal and switching the second latch output signal to that of the input signal.

### PRIORITY CLAIM

This application claims the priority of U.S. Provisional Patent Application No. 61/532,197 (by Tom Youssef, filed Sep. 8, 2011, and entitled “INPUT BUFFER TO ACCEPT ANY EXTERNAL SIGNAL TRANSITIONING LEVEL VALUE”) of which the entire contents are incorporated herein by reference.

### BACKGROUND

In various electronic systems, an input buffer is often used as an intermediary module between a signal from a driver module and a driven module. The input buffer or intermediary module can function to step the signal level up or down to an appropriate level for use by the driven module, to prevent the driven module from loading down the driver module, and/or to otherwise prevent the interaction of the driven and driver modules from interfering with the operation of the system.

In general, the intended application will identify a design specification or protocol which spells out the ranges of various system parameters such as clock and signal speed, signal levels, and voltage supply levels that must be met in order for the system to function properly.

### BRIEF DESCRIPTION OF THE DRAWINGS

The accompanying drawings provide visual representations which will be used to more fully describe various representative embodiments and can be used by those skilled in the art to better understand the representative embodiments disclosed herein and their inherent advantages. In these drawings, like reference numerals identify corresponding elements.

FIG. 1A is a block diagram of a digital input buffer as described in various representative embodiments.

FIG. 1B is a schematic of a digital input buffer as described in various representative embodiments.

FIG. 2 is a schematic of another digital input buffer as described in various representative embodiments.

FIG. 3 is a schematic of still another digital input buffer as described in various representative embodiments.

FIG. 4 is a schematic of yet another digital input buffer as described in various representative embodiments.

FIG. 5 is a flow chart of a method for operating the digital input buffer as described in each of FIGS. 1-4.

### DETAILED DESCRIPTION

As shown in the drawings for purposes of illustration, novel techniques are disclosed herein for a fast, low power, broad input voltage input range digital input buffer. Previous input buffers have often used large resistive values to limit the steady state current resulting in longer RC delays and/or have been more restrictive in their allowed range of input signal levels than those which are disclosed in the following.

In representative embodiments, the input buffers disclosed are low power devices that are also fast and are input signal level insensitive. A voltage regulator operating in weak inversion is used to supply power to an inverter in the level shifter which results in a low power input buffer that is insensitive to the input signal level. Input and output stages of the input buffers each comprise a pair of n-channel and p-channel field effect transistors. In the steady states of the input buffer, each pair of field effect transistors, the inverter, and the voltage regulator draw no more than their leakage currents which in combination with the voltage regulator operating in weak inversion results in a low power device. The operating DC current could be in the 150 nanoamp range. In addition, the input buffer does not include large resistors which are often used to limit the steady state currents but which result in larger RC circuitry delays. As such, the representative embodiments disclosed herein do not exhibit the large RC delays which can severely limit the operating speed of an input buffer.

The representative embodiments disclosed herein are capable of implementation in various applications including those that operate as a slave device on a bus such as those in the I2C (2 wire bus) protocol. As an example, the power supply for such applications could provide 5V with the serial clock line (SCL) and serial data line (SDA) being driven by signals between 0 and 1.5V and operating at clock speeds up to the maximum 3.4 MHz specified for the I2C protocol. Only approximately 150 nanoamp DC current would be pulled under typical conditions to power the input buffer with the voltage regulator operating in weak inversion.

The embodiments described herein are appropriate for use in any application or product using a wire bus to communicate with the CPU, such as mobile phones, digital cameras, etc. Such products may use a digital interface with the system where the signals are not transitioning rail-to-rail, although applications with rail-to-rail transitions are covered too. Much less current is required, a clear advantage in battery applications. Given the embodiments provided herein, all I2C protocols regarding timing and speed are satisfied, and the embodiments are applicable as well to other communication protocols.

While the present invention is subject to embodiment in many different forms, there is shown in the drawings and will herein be described in detail one or more specific embodiments, with the understanding that the present disclosure is to be considered as exemplary of the principles of the invention and not intended to limit the invention to the specific embodiments shown and described. In the following description and in the several figures of the drawings, like reference numerals are used to describe the same, similar or corresponding parts in the several views of the drawings.

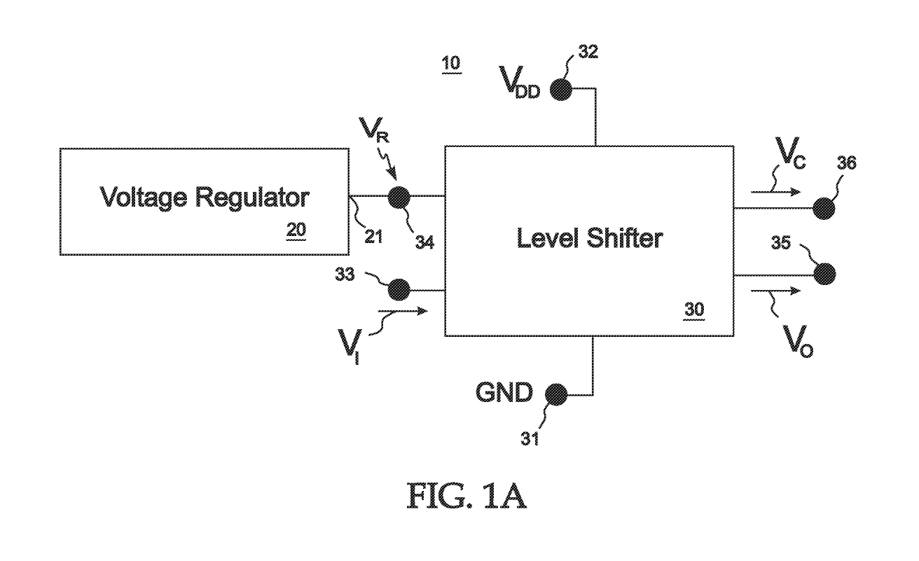

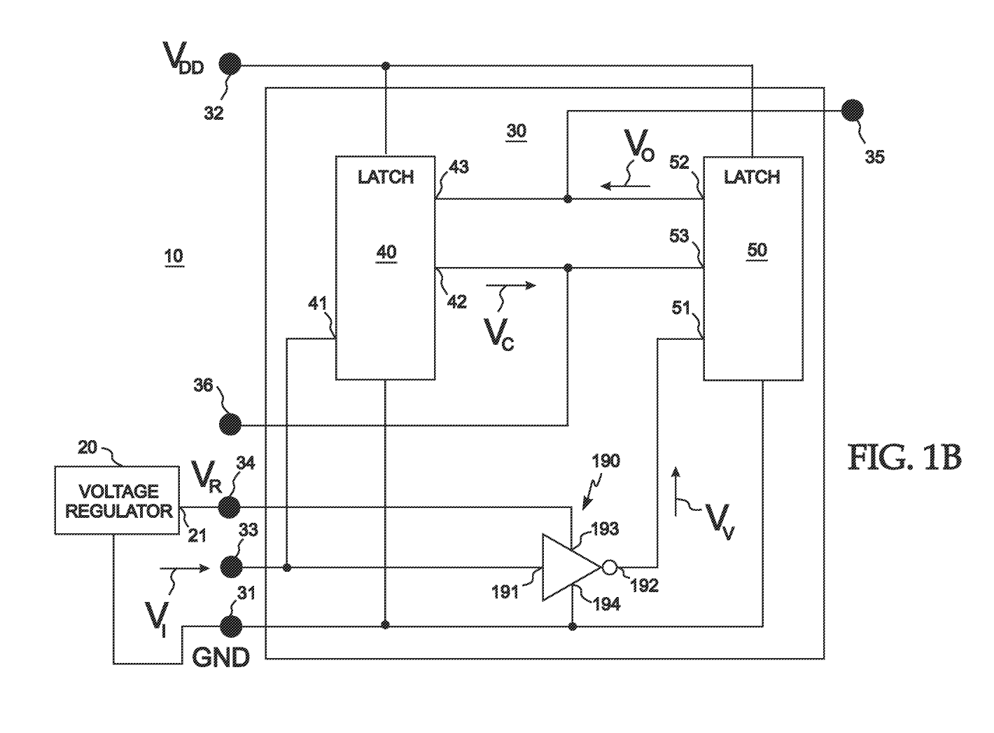

FIG. 1A is a block diagram of a digital input buffer 10 as described in various representative embodiments. In FIG. 1A, the digital input buffer 10 which is also referred to herein as the input buffer 10 comprises a voltage regulator 20 having a regulator output 21 and a level shifter 30. Operating in weak inversion, the voltage regulator 20 outputs a regulated potential V_{R} relative to a first potential GND at the regulator output 21. The level shifter 30 has a first potential contact 31 configured for coupling to a DC power source at the first potential GND which may also be referred to herein as the ground potential GND and as the reference potential GND, a second potential contact 32 configured for coupling to the DC power source at a second potential V_{DD} which may also be referred to herein as a supply voltage V_{DD}, a reference input 34 coupled to the regulator output 21, a buffer input 33 configured for receiving an input signal V_{I}, a first output contact 35 configured for outputting an output signal V_{O} in response to the input signal V_{I}, and a second output contact 36 configured for outputting an output complement signal V_{C} in response to the input signal V_{I}. The output complement signal V_{C} is the complement of the output signal V_{O}.

As will be observed in the following discussion of various representative embodiments, these embodiments which use the output of the voltage regulator 20 to power an inverter can provide a fast, low power, input buffer for digital circuits that is input signal level insensitive.

FIG. 1B is a schematic of a digital input buffer 10 as described in various representative embodiments. In FIG. 1B, the input buffer 10 comprises a voltage regulator 20 and a level shifter 30. Typically operating in weak inversion, the voltage regulator 20 outputs a regulated potential V_{R} relative to a first potential GND at a regulator output 21. The level shifter 30 has a first potential contact 31 configured for coupling to a DC power source at the first potential GND which may also be referred to herein as the ground potential GND and as the reference potential GND, a second potential contact 32 configured for coupling to the DC power source at a second potential V_{DD}, a reference input 34 configured for coupling to the regulator output 21, a buffer input 33 configured for receiving an input signal V_{I}, a first output contact 35 configured for outputting an output signal V_{O} in response to the input signal V_{I}, and a second output contact 36 configured for outputting an output complement signal V_{C} in response to the input signal V_{I}. The output complement signal V_{C} is the complement of the output signal V_{O}.

The level shifter 30 comprises a first latch 40, a second latch 50, and an inverter 190. The first latch 40 has a first latch input 41, a first latch output 42, and a first latch enable input 43. The second latch 50 has a second latch input 51, a second latch output 52, and a second latch enable input 53. The inverter 190 has an inverter input 191, an inverter output 192, a first inverter power contact 193, and a second inverter power contact 194. The potential at the inverter output 192 is the complement of the potential at the inverter input 191.

Power is supplied to the first and second latches 40, 50 via the supply potential V_{DD} at the second potential contact 32 and the reference potential GND at the first potential contact 31. The inverter 190 is supplied power via the regulated potential V_{R} from the voltage regulator 20 at the reference input 34 and the reference potential GND. The inverter 190 is configured for receiving an input signal V_{I} at its input 191 which is coupled to the buffer input 33 and to the first latch input 41. The inverter 190 outputs an inverter output signal V_{V} at its output 192. The inverter output 192 is coupled to the second latch input 51. The second latch output 52 is coupled to the first latch enable input 43 and to the first output contact 35, and the second latch enable input 53 is coupled to the first latch output 42, and to the second output contact 36. This arrangement provides positive feedback from the first latch 40 to the second latch 50 and from the second latch 50 to the first latch 40 which results in a first latch output signal V_{C} from the first latch output 42 coupled to the second latch enable input 53 and a second latch output signal V_{O} from the second latch output 52 coupled to the first latch enable input 43 enabling switching the first latch output signal V_{C} to the complement of the input signal V_{I} and enabling switching the second latch output signal V_{O} to that of the input signal V_{I}.

In operation, if the input signal V_{I} is LOGIC LOW, the output signal V_{O} at the first output contact 35 is a LOGIC LOW, and the output complement signal V_{C} at the second output contact 36 is a LOGIC HIGH. Conversely, if the input signal V_{I} is LOGIC HIGH, the output signal V_{O} at the first output contact 35 is a LOGIC HIGH and the output complement signal V_{C} at the second output contact 36 is a LOGIC LOW.

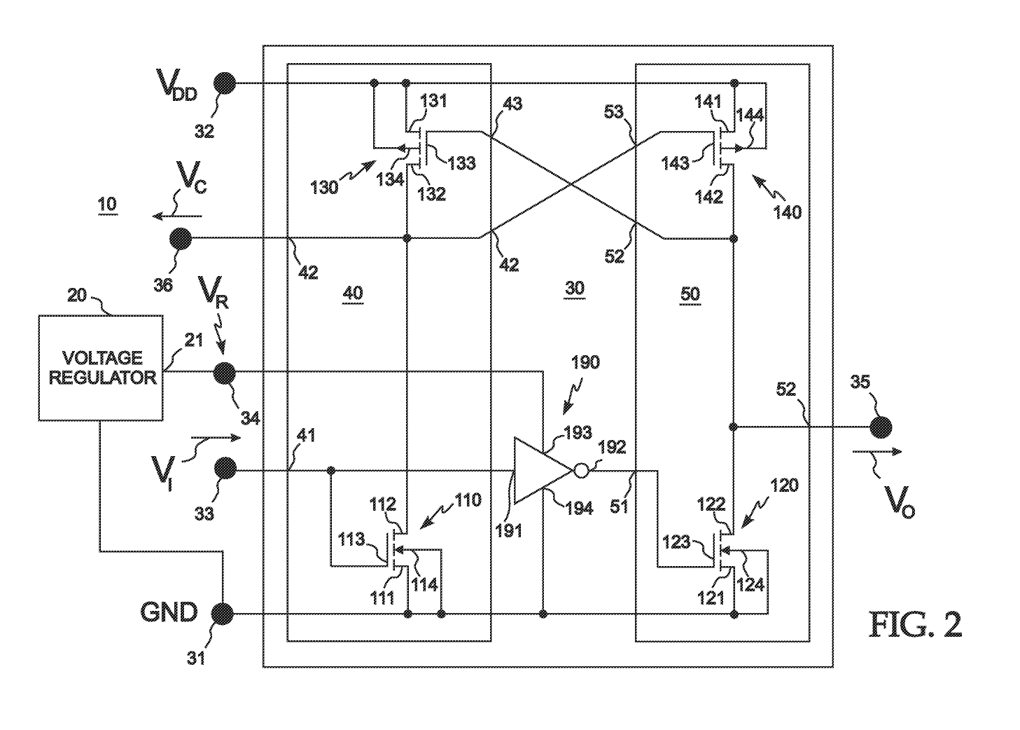

FIG. 2 is a schematic of another digital input buffer 10 as described in various representative embodiments. In FIG. 2, the input buffer 10 comprises a voltage regulator 20 and a level shifter 30. Typically operating in weak inversion, the voltage regulator 20 outputs a regulated potential V_{R} relative to a first potential GND at a regulator output 21. The level shifter 30 has a first potential contact 31 configured for coupling to a DC power source at the first potential GND which may also be referred to herein as the ground potential GND and as the reference potential GND, a second potential contact 32 configured for coupling to the DC power source at a second potential V_{DD}, a reference input 34 configured for coupling to the regulator output 21, a buffer input 33 configured for receiving an input signal V_{I}, a first output contact 35 configured for outputting an output signal V_{O} in response to the input signal V_{I}, and a second output contact 36 configured for outputting an output complement signal V_{C} in response to the input signal V_{I}. The output complement signal V_{C} is the complement of the output signal V_{O}. In this representative embodiment, the second potential V_{DD} is positive relative to the ground potential GND.

The level shifter 30 comprises a first latch 40, a second latch 50, and an inverter 190 which are coupled as shown in FIG. 1B. The first latch 40 comprises an n-channel, enhancement mode first field effect transistor (FET) 110 and a p-channel, enhancement mode third field effect transistor (FET) 130. The second latch 50 comprises an n-channel, enhancement mode second field effect transistor (FET) 120 and a p-channel, enhancement mode fourth field effect transistor (FET) 140. The first FET 110 has a first-FET source 111, a first-FET drain 112, a first-FET gate 113, and a first-FET substrate 114; the second FET 120 has a second-FET source 121, a second-FET drain 122, a second-FET gate 123, and a second-FET substrate 124; the third FET 130 has a third-FET source 131, a third-FET drain 132, a third-FET gate 133, and a third-FET substrate 134; and the fourth FET 140 has a fourth-FET source 141, a fourth-FET drain 142, a fourth-FET gate 143, and a fourth-FET substrate 144. The inverter 190 has an inverter input 191, an inverter output 192, a first inverter power contact 193, and a second inverter power contact 194. The potential at the inverter output 192 is the complement of the potential at the inverter input 191.

The first-FET source 111, first-FET substrate 114, second-FET source 121, second-FET substrate 124 and second inverter power contact 194 are coupled to the first potential contact 31 which is configured for coupling to the ground potential GND of a power source. The third-FET source 131, third-FET substrate 134, fourth-FET source 141 and fourth-FET substrate 144 are coupled to the second potential contact 32 which is configured for coupling to the second potential V_{DD}. The first-FET gate 113 and inverter input 191 are coupled to the first latch input 41 and to the buffer input 33. The inverter output 192 is coupled to the second latch input 51 and to the second-FET gate 123. The first inverter power contact 193 is coupled to the reference input 34. The fourth-FET drain 142 and third-FET gate 133 are coupled to the second-FET drain 122, to the second latch output 52, to the first latch enable input 43, and to the first output contact 35. The third-FET drain 132 and fourth-FET gate 143 are coupled to the first-FET drain 112, to the first latch output 42, to the second latch enable input 53, and to the second output contact 36.

In operation, if the input signal V_{I} is LOGIC LOW, the first FET 110 is turned OFF and the output of the inverter 190 is LOGIC HIGH which turns the second FET 1200N. The ON state of the second FET 120 forces the third FET 130 into an ON state with the result that the third-FET drain 132, the first-FET drain 112, and the fourth-FET gate 143 are LOGIC HIGH. The LOGIC HIGH state of the fourth-FET gate 143 forces the fourth FET 140 into an OFF state. This situation results in the output signal V_{O} at the first output contact 35 driven into the LOGIC LOW condition and the output complement signal V_{C} at the second output contact 36 driven into the LOGIC HIGH condition.

Conversely, if the input signal V_{I} is LOGIC HIGH, the first FET 110 is turned ON and the output of the inverter 190 is LOGIC LOW which turns the second FET 120 OFF. The OFF state of the second FET 120 forces the third FET 130 into an OFF state with the result that the third-FET drain 132, the first-FET drain 112, and the fourth-FET gate 143 are LOGIC LOW. The LOGIC LOW state of the fourth-FET gate 143 forces the fourth FET 140 into an ON state. This situation results in the output signal V_{O} at the first output contact 35 driven into the LOGIC HIGH condition and the output complement signal V_{C} at the second output contact 36 driven into the LOGIC LOW condition.

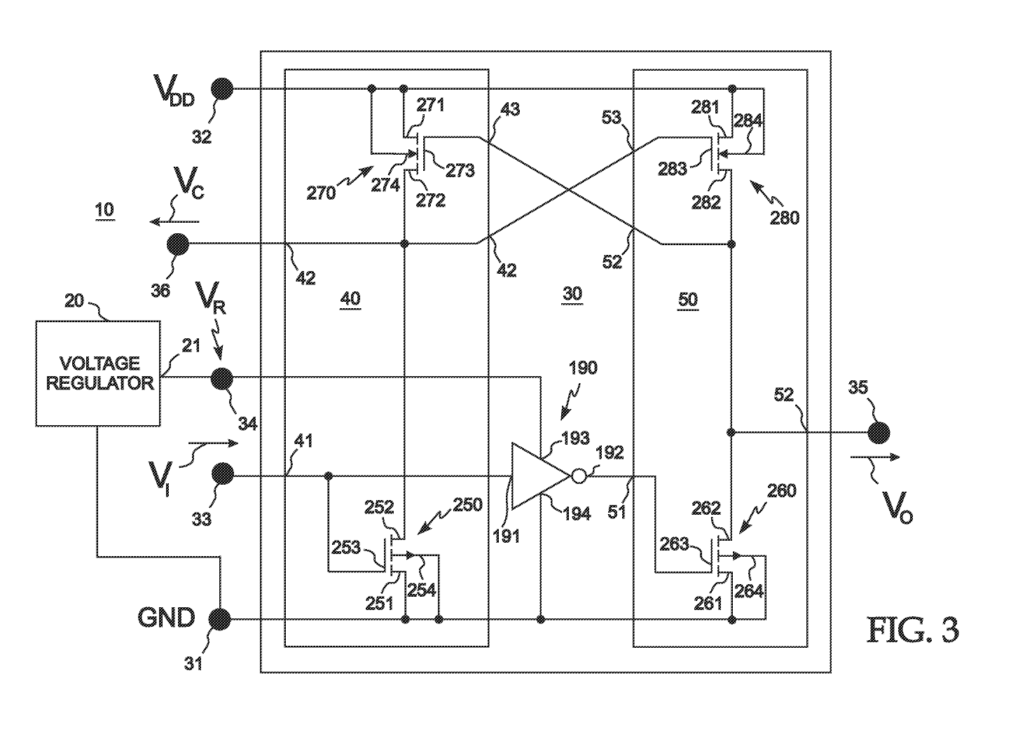

FIG. 3 is a schematic of still another digital input buffer 10 as described in various representative embodiments. In FIG. 3, the input buffer 10 comprises a voltage regulator 20 and a level shifter 30. Typically operating in weak inversion, the voltage regulator 20 outputs a regulated potential V_{R} relative to a first potential GND at a regulator output 21. The level shifter 30 has a first potential contact 31 configured for coupling to a DC power source at a first potential GND which may also be referred to herein as the ground potential GND and as the reference potential GND, a second potential contact 32 configured for coupling to the DC power source at a second potential V_{DD}, a reference input 34 configured for coupling to the regulator output 21, a buffer input 33 configured for receiving an input signal V_{I}, a first output contact 35 configured for outputting an output signal V_{O} in response to the input signal V_{I}, and a second output contact 36 configured for outputting an output complement signal V_{C} in response to the input signal V_{I}. The output complement signal V_{C} is the complement of the output signal V_{O}. In this representative embodiment, the second potential V_{DD} is negative relative to the ground potential GND.

The level shifter 30 comprises a first latch 40, a second latch 50, and an inverter 190 which are coupled as shown in FIG. 1B. The first latch 40 comprises a p-channel, enhancement mode fifth field effect transistor (FET) 250 and an n-channel, enhancement mode seventh field effect transistor (FET) 270. The second latch 50 comprises a p-channel, enhancement mode sixth field effect transistor (FET) 260 and an n-channel, enhancement mode eighth field effect transistor (FET) 280. The fifth FET 250 has a fifth-FET source 251, a fifth-FET drain 252, a fifth-FET gate 253, and a fifth-FET substrate 254; the sixth FET 260 has a sixth-FET source 261, a sixth-FET drain 262, a sixth-FET gate 263, and a sixth-FET substrate 264; the seventh FET 270 has a seventh-FET source 271, a seventh-FET drain 272, a seventh-FET gate 273, and a seventh-FET substrate 274; and the eighth FET 280 has an eighth-FET source 281, an eighth-FET drain 282, an eighth-FET gate 283, and an eighth-FET substrate 284. The inverter 190 has an inverter input 191, an inverter output 192, a first inverter power contact 193, and a second inverter power contact 194. The potential at the inverter output 192 is the complement of the potential at the inverter input 191.

The fifth-FET source 251, fifth-FET substrate 254, sixth-FET source 261, sixth-FET substrate 264 and second inverter power contact 194 are coupled to the first potential contact 31 which is configured for coupling to the ground potential GND of a power source. The seventh-FET source 271, seventh-FET substrate 274, eighth-FET source 281, and eighth-FET substrate 284 are coupled to the second potential contact 32 which is configured for coupling to the second potential V_{DD}. The fifth-FET gate 253 and inverter input 191 are coupled to the first latch input 41 and to the buffer input 33. The inverter output 192 is coupled to the second latch input 51 and to the sixth-FET gate 263. The first inverter power contact 193 is coupled to the reference input 34. The eighth-FET drain 282 and seventh-FET gate 273 are coupled to the sixth-FET drain 262, to the second latch output 52, to the first latch enable input 43, and to the first output contact 35. The seventh-FET drain 272 and eighth-FET gate 283 are coupled to the fifth-FET drain 252, to the first latch output 42, to the second latch enable input 53, and to the second output contact 36.

In operation, if the input signal V_{I} is LOGIC LOW, the fifth FET 250 is turned OFF and the output of the inverter 190 is LOGIC HIGH which turns the sixth FET 2600N. The ON state of the sixth FET 260 forces the seventh FET 270 into an ON state with the result that the seventh-FET drain 272, the fifth-FET drain 252, and the eighth-FET gate 283 are LOGIC HIGH. The LOGIC HIGH state of the eighth-FET gate 283 forces the eighth FET 280 into an OFF state. This situation results in the output signal V_{O} at the first output contact 35 driven into the LOGIC LOW condition and the output complement signal V_{C} at the second output contact 36 driven into the LOGIC HIGH condition.

Conversely, if the input signal V_{I} is LOGIC HIGH, the fifth FET 250 is turned ON and the output of the inverter 190 is LOGIC LOW which turns the sixth FET 260 OFF. The OFF state of the sixth FET 260 forces the seventh FET 270 into an OFF state with the result that the seventh-FET drain 272, the fifth-FET drain 252, and the eighth-FET gate 283 are LOGIC LOW. The LOGIC LOW state of the eighth-FET gate 283 forces the eighth FET 280 into an ON state. This situation results in the output signal V_{O} at the first output contact 35 driven into the LOGIC HIGH condition and the output complement signal V_{C} at the second output contact 36 driven into the LOGIC LOW condition.

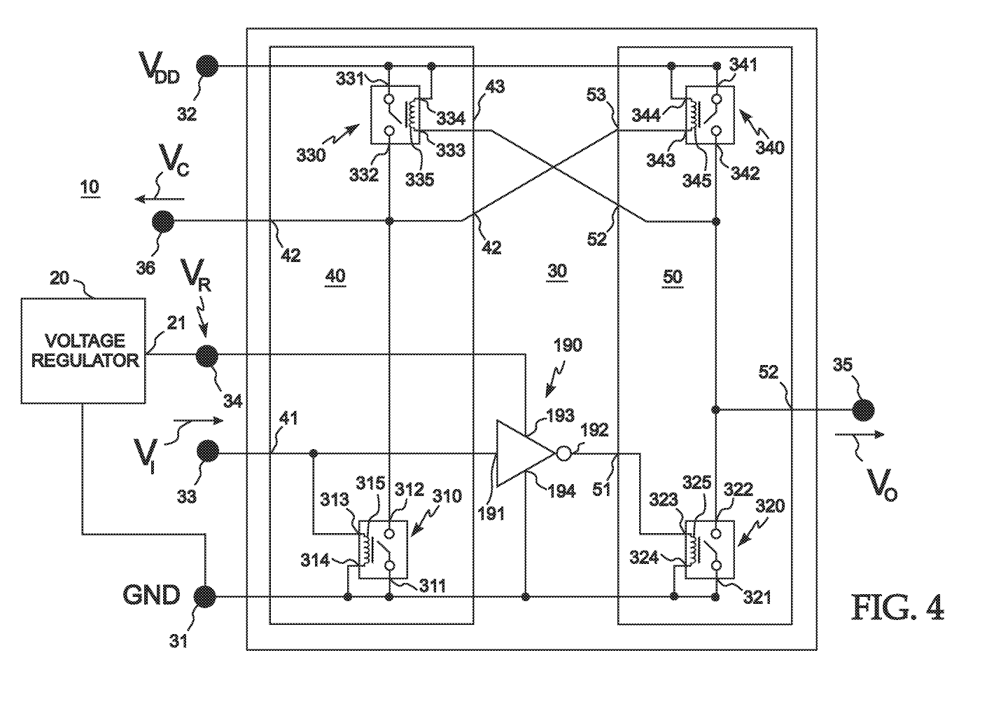

FIG. 4 is a schematic of yet another digital input buffer 10 as described in various representative embodiments. In FIG. 4, the input buffer 10 comprises a voltage regulator 20 and a level shifter 30. Typically operating in weak inversion, the voltage regulator 20 outputs a regulated potential V_{R} relative to a first potential GND at a regulator output 21. The level shifter 30 has a first potential contact 31 configured for coupling to a DC power source at a first potential GND which may also be referred to herein as the ground potential GND and as the reference potential GND, a second potential contact 32 configured for coupling to the DC power source at a second potential V_{DD}, a reference input 34 configured for coupling to the regulator output 21, a buffer input 33 configured for receiving an input signal V_{I}, a first output contact 35 configured for outputting an output signal V_{O} in response to the input signal V_{I}, and a second output contact 36 configured for outputting an output complement signal V_{C} in response to the input signal V_{I}. The output complement signal V_{C} is the complement of the output signal V_{O}. In this representative embodiment, the second potential V_{DD} can be positive or negative relative to the ground potential GND but is assumed to be positive.

The level shifter 30 comprises a first latch 40, a second latch 50, and an inverter 190 which are coupled as shown in FIG. 1B. The first latch 40 comprises a first switch 310 and a third switch 330. The second latch 50 comprises a second switch 320 and a fourth switch 340. The first switch 310 has a first-switch first contact 311, a first-switch second contact 312, and a first actuator 315. The first actuator 315 has a first-switch first control contact 313 and a first-switch second control contact 314. If the first actuator 315 is activated by a potential difference between the first-switch first and second control contacts 313,314, the first-switch first contact 311 is coupled to the first-switch second contact 312. Otherwise, the first-switch first contact 311 is decoupled from the first-switch second contact 312. The second switch 320 has a second-switch first contact 321, a second-switch second contact 322, and a second actuator 325. The second actuator 325 has a second-switch first control contact 323 and a second-switch second control contact 324. If the second actuator 325 is activated by a potential difference between the second-switch first and second control contacts 323,324, the second-switch first contact 321 is coupled to the second-switch second contact 322. Otherwise, the second-switch first contact 321 is decoupled from the second-switch second contact 322. The third switch 330 has a third-switch first contact 331, a third-switch second contact 332, and a third actuator 335. The third actuator 335 has a third-switch first control contact 333 and a third-switch second control contact 334. If the third actuator 335 is activated by a potential difference between the third-switch first and second control contacts 333,334, the third-switch first contact 331 is coupled to the third-switch second contact 332. Otherwise, the third-switch first contact 331 is decoupled from the third-switch second contact 332. The fourth switch 340 has a fourth-switch first contact 341, a fourth-switch second contact 342, and a fourth actuator 345. The fourth actuator 345 has a fourth-switch first control contact 343 and a fourth-switch second control contact 344. If the fourth actuator 345 is activated by a potential difference between the fourth-switch first and second control contacts 343,344, the fourth-switch first contact 341 is coupled to the fourth-switch second contact 342. Otherwise, the fourth-switch first contact 341 is decoupled from the fourth-switch second contact 342. The inverter 190 has an inverter input 191, an inverter output 192, a first inverter power contact 193, and a second inverter power contact 194. The potential at the inverter output 192 is the complement of the potential at the inverter input 191.

The first-switch first contact 311, the first-switch second control contact 314, the second-switch first contact 321, the second-switch second control contact 324, and the second inverter power contact 194 are coupled to the first potential contact 31 which is configured for coupling to the ground potential GND of a power source. The third-switch first contact 331, the third-switch second control contact 334, the fourth-switch first contact 341, and the fourth-switch second control contact 344 are coupled to the second potential contact 32 which is configured for coupling to the second potential V_{DD}. The first-switch first control contact 313 and inverter input 191 are coupled to the first latch input 41 and to the buffer input 33. The inverter output 192 is coupled to the second latch input 51 and to the second-switch first control contact 323. The first inverter power contact 193 is coupled to the reference input 34. The fourth-switch second contact 342 and third-switch first control contact 333 are coupled to the second-switch second contact 322, to the second latch output 52, to the first latch enable input 43, and to the first output contact 35. The third-switch second contact 332 and fourth-switch first control contact 343 are coupled to the first-switch second contact 312, to the first latch output 41, to the second latch enable input 53, and to the second output contact 36.

In operation, if the input signal V_{I} is LOGIC LOW (i.e., at or near the first potential GND), the first actuator 315 via the first-switch first and second control contacts 313,314 is not actuated which results in the first-switch first contact 311 decoupled from the first-switch second contact 312. Also since the input signal V_{I} is LOGIC LOW, the output of the inverter 190 is LOGIC HIGH which activates the second actuator 325 via the second-switch first and second control contacts 323,324 resulting in the coupling of the second-switch first contact 321 to the second-switch second contact 322, thereby activating the third actuator 335 via the third-switch first and second control contacts 333,334 which couples the third-switch first contact 331 to the third-switch second contact 332. Since the fourth-switch first control contact 343 is held at the second potential V_{DD}, the fourth actuator 345 is not actuated and the fourth-switch first contact 341 and the fourth-switch second contact 342 are decoupled. This situation results in the output signal V_{O} at the first output contact 35 driven into the LOGIC LOW condition (first potential GND) and the output complement signal V_{C} at the second output contact 36 driven into the LOGIC HIGH condition (second potential V_{DD}).

Conversely, if the input signal V_{I} is LOGIC HIGH, the first actuator 315 via the first-switch first and second control contacts 313,314 is actuated which results in the first-switch first contact 311 coupled to the first-switch second contact 312. Also since the input signal V_{I} is LOGIC HIGH, the output of the inverter 190 is LOGIC LOW which does not actuate the second actuator 325 via the second-switch first and second control contacts 323,324 resulting in the decoupling of the second-switch first contact 321 from the second-switch second contact 322, whereby the third actuator 335 is not actuated via the third-switch first and second control contacts 333,334 which decouples the third-switch first contact 331 from the third-switch second contact 332. Since the fourth-switch first control contact 343 is held at the first potential GND, the fourth actuator 345 is actuated which couples the fourth-switch first contact 341 to the fourth-switch second contact 342. This situation results in the output signal V_{O} at the first output contact 35 driven into the LOGIC HIGH condition (second potential V_{DD}) and the output complement signal V_{C} at the second output contact 36 driven into the LOGIC LOW condition (first potential GND).

In representative embodiments, the switches 310, 320, 330, 340 of FIG. 4 could be implemented using any appropriate switching devices including, but not limited to, any of various relays, any of various vacuum tubes, any of various solid state devices, and any of various integrated circuits. The relays could include single pole single throw relays and single pole double throw relays among others. The vacuum tubes could include triodes among others. The solid state devices could include PNP bipolar junction transistors, NPN bipolar junction transistors, n-channel junction gate field-effect transistors, p-channel junction gate field-effect transistors, n-channel metal-oxide-semiconductor field effect transistors, and p-channel metal-oxide-semiconductor field effect transistors among others. The integrated circuits could include operational amplifiers and solid state switches among others.

Note also that in a representative embodiment the switches 310, 320, 330, 340 of FIG. 4 can be replaced respectively by the field effect transistors 110, 120, 130, 140 of FIG. 2. In particular in reference to FIG. 2, the first switch 310 can be replaced by the first FET 110 with the first-switch first contact 311 replaced by the first-FET source 111, the first-switch second contact 312 replaced by the first-FET drain 112, the first-switch first control contact 313 replaced by the first-FET gate 113, first-switch second control contact 314 replaced by the first-FET substrate 114 and with the first actuator 315 replaced by the structure of the first-FET gate 113 to first-FET substrate 114; the second switch 320 can be replaced by the second FET 120 with the second-switch first contact 321 replaced by the second-FET source 121, the second-switch second contact 322 replaced by the second-FET drain 122, the second-switch first control contact 323 replaced by the second-FET gate 123, second-switch second control contact 324 replaced by the second-FET substrate 124 and with the second actuator 325 replaced by the structure of the second-FET gate 123 to second-FET substrate 124; the third switch 330 can be replaced by the third FET 130 with the third-switch first contact 331 replaced by the third-FET source 131, the third-switch second contact 332 replaced by the third-FET drain 132, the third-switch first control contact 333 replaced by the third-FET gate 133, third-switch second control contact 334 replaced by the third-FET substrate 134 and with the third actuator 335 replaced by the structure of the third-FET gate 133 to third-FET substrate 134; and the fourth switch 340 can be replaced by the fourth FET 140 with the fourth-switch first contact 341 replaced by the fourth-FET source 141, the fourth-switch second contact 342 replaced by the fourth-FET drain 142, the fourth-switch first control contact 343 replaced by the fourth-FET gate 143, the fourth-switch second control contact 344 replaced by the fourth-FET substrate 144 and with the fourth actuator 345 replaced by the structure of the fourth-FET gate 143 to fourth-FET substrate 144. In this embodiment the second potential V_{DD} is positive relative to the first potential (ground potential) GND.

Also note that in another representative embodiment the switches 310, 320, 330, 340 of FIG. 4 can be replaced respectively by the field effect transistors 250, 260, 270, 280 of FIG. 3. In particular in reference to FIG. 3, the first switch 310 can be replaced by the fifth FET 250 with the first-switch first contact 311 replaced by the fifth-FET source 251, the first-switch second contact 312 replaced by the fifth-FET drain 252, the first-switch first control contact 313 replaced by the fifth-FET gate 253, first-switch second control contact 314 replaced by the fifth-FET substrate 254 and with the first actuator 315 replaced by the structure of the fifth-FET gate 253 to fifth-FET substrate 254; the second switch 320 can be replaced by the sixth FET 260 with the second-switch first contact 321 replaced by the sixth-FET source 261, the second-switch second contact 322 replaced by the sixth-FET drain 262, the second-switch first control contact 323 replaced by the sixth-FET gate 263, the second-switch second control contact 324 replaced by the sixth-FET substrate 264 and with the second actuator 325 replaced by the structure of the sixth-FET gate 263 to sixth-FET substrate 264; the third switch 330 can be replaced by the seventh FET 270 with the third-switch first contact 331 replaced by the seventh-FET source 271, the third-switch second contact 332 replaced by the seventh-FET drain 272, the third-switch first control contact 333 replaced by the seventh-FET gate 273, the third-switch second control contact 334 replaced by the seventh-FET substrate 274 and with the third actuator 335 replaced by the structure of the seventh-FET gate 273 to seventh-FET substrate 274; and the fourth switch 340 can be replaced by the eighth FET 280 with the fourth-switch first contact 341 replaced by the eighth-FET source 281, the fourth-switch second contact 342 replaced by the eighth-FET drain 282, the fourth-switch first control contact 343 replaced by the eighth-FET gate 283, the fourth-switch second control contact 344 replaced by the eighth-FET substrate 284 and with the fourth actuator 345 replaced by the structure of the eighth-FET gate 283 to eighth-FET substrate 284. In this embodiment the second potential V_{DD} is negative relative to the first potential (ground potential) GND.

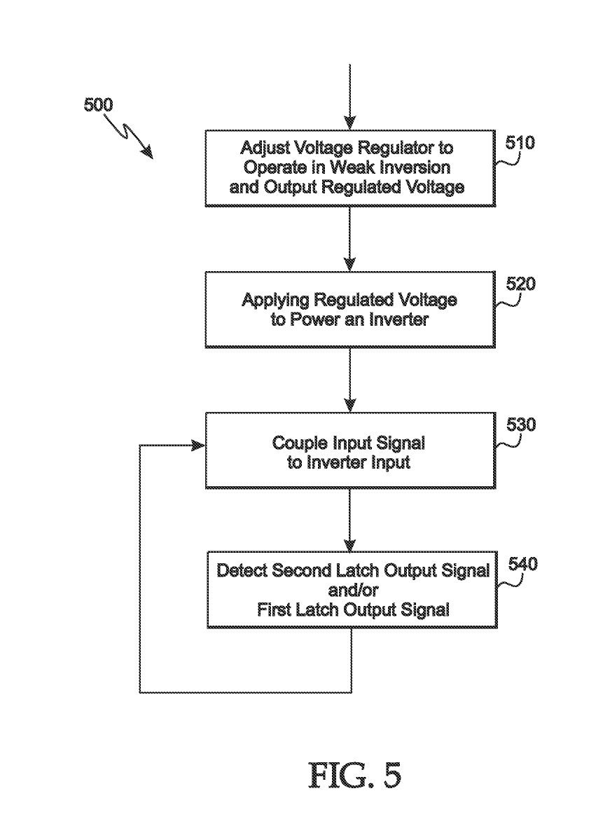

FIG. 5 is a flow chart of a method 400 for operating a digital input buffer 10 as described in each of FIGS. 1A, 1B, and 2-4. In block 510 of FIG. 5, the voltage regulator 20 is adjusted to operate in weak inversion while outputting a regulated potential V_{R}. Block 510 then transfers control to block 520.

In block 520, the regulated potential V_{R} is coupled as a power source to the inverter 190, as shown in FIGS. 1B and 2-4, the inverter 190 has its input 191 coupled to an input 41 of a first latch 40 and has its output 192 coupled to an input 51 of a second latch input 50, and an output 42 of the first latch 40 is coupled to an enable input 53 of the second latch 50 and an output 52 of the second latch 50 is coupled to an enable input 43 of the first latch 40. Block 520 then transfers control to block 530.

In block 530, an input signal V_{I} is coupled to the inverter input 191. Block 530 then transfers control to block 540.

In block 540, the resultant second latch output signal (output signal) V_{O} is detected at the second latch output 52 and/or the resultant first latch output signal (output complement signal) V_{C} is detected at the first latch output 42. Block 540 the transfers control back to block 530.

In a representative embodiment, a digital input buffer 10 is disclosed. The digital input buffer 10 comprises a voltage regulator 20 configured for operating in weak inversion and for outputting a regulated potential V_{R}, an inverter 190 having as its power source the regulated potential V_{R}, configured for receiving an input signal V_{I} at its input 191, and outputting an inverter output signal V_{V} at its output 192, a first latch 40 having its input 41 coupled to the inverter input 191, having an output 42, and having an enable input 43, and a second latch 50 having its input 51 coupled to the inverter output 192, having an output 52 coupled to the first latch enable input 43, and having an enable input 53 coupled to the first latch output 42. A first latch output signal V_{C} from the first latch output 42 coupled to the second latch enable input 53 and a second latch output signal V_{O} from the second latch output 52 coupled to the first latch enable input 43 enable switching the first latch output signal V_{C} to the complement of the input signal V_{I} and enable switching the second latch output signal V_{O} to that of the input signal V_{I}.

In another representative embodiment, a method 500 is disclosed. The method 500 comprises adjusting 510 a voltage regulator 20 to operate in weak inversion while outputting a regulated potential V_{R}, applying 520 the regulated potential V_{R} to power an inverter 190, applying an input signal V_{I} to the inverter input 191, and detecting a second latch output signal V_{O} at the second latch output 52 and/or its complement first latch output signal V_{C} at the first latch output 42. The inverter 190 has its input 191 coupled to an input 41 of a first latch 40 and has its output 192 coupled to an input 51 of a second latch 50; and an output 42 of the first latch 42 is coupled to an enable input 53 of the second latch 50 and an output 52 of the second latch 50 is coupled to an enable input 43 of the first latch 40.

In yet another representative embodiment, a digital input buffer 10 is disclosed. The input buffer 10, comprises a voltage regulator 20 configured for operating in weak inversion and for outputting a positive regulated potential V_{R} relative to a reference potential GND; an inverter 190 having as its power source the regulated potential V_{R} of the voltage regulator 20, configured for receiving an input signal V_{I} at its input 191, and having an inverter output 192; a first field effect transistor (FET) 110 having its gate 113 coupled to the inverter 190 input 191 and having its source 111 and substrate 114 configured for coupling to the reference potential GND; a second FET 120, having its gate 123 coupled to the inverter output 192 and having its source 121 and substrate 124 configured for coupling to the reference potential GND; a third FET 130, having its drain 132 coupled to the drain 112 of the first FET 110 and having its source 131 and substrate 134 configured for coupling to a supply voltage V_{DD}; and a fourth FET 140, having its gate 143 coupled to the drain 112 of first FET 110, having its drain 142 coupled to the gate 133 of the third FET 130 and to the drain 122 of the second FET 120, and having its source 141 and substrate 144 configured for coupling to the supply voltage V_{DD}. The first FET 110 is an n-channel, enhancement mode field effect transistor; the second FET 120 is an n-channel, enhancement mode field effect transistor; the third FET 130 is a p-channel, enhancement mode field effect transistor; and the fourth FET 140 is a p-channel, enhancement mode field effect transistor. The supply voltage V_{DD} is positive relative to the reference potential GND.

In still another representative embodiment, a digital input buffer 10 is disclosed. The input buffer 10 comprises a voltage regulator 20 configured for operating in weak inversion and for outputting a negative regulated potential V_{R} relative to a reference potential GND; an inverter 190 having as its power source the regulated potential V_{R} of the voltage regulator 20, configured for receiving an input signal V_{I} at its input 191, and having an inverter output 192; a fifth field effect transistor (FET) 250 having its gate 253 coupled to the inverter 190 input 191 and having its source 251 and substrate 254 configured for coupling to the reference potential GND; a sixth FET 260, having its gate 263 coupled to the inverter output 192 and having its source 261 and substrate 264 configured for coupling to the reference potential GND; a seventh FET 270, having its drain 272 coupled to the drain 252 of the fifth FET 250 and having its source 271 and substrate 274 configured for coupling to a supply voltage V_{DD}; and an eighth FET 280, having its gate 283 coupled to the drain 252 of fifth FET 250, having its drain 282 coupled to the gate 273 of the seventh FET 270 and to the drain 262 of the sixth FET 260, and having its source 281 and substrate 284 configured for coupling to the supply voltage V_{DD}. The fifth FET 250 is a p-channel, enhancement mode field effect transistor; the sixth FET 260 is a p-channel, enhancement mode field effect transistor; the seventh FET 270 is an n-channel, enhancement mode field effect transistor; and the eighth FET 280 is a p-channel, enhancement mode field effect transistor. The supply voltage V_{DD} is positive relative to the reference potential GND.

In yet still another representative embodiment, a digital input buffer 10 is disclosed. The input buffer 10 comprises a voltage regulator 20 configured for operating in weak inversion and for outputting a regulated potential V_{R} relative to a reference potential GND; an inverter 190 having as its power source the regulated potential V_{R} of the voltage regulator 20, configured for receiving an input signal V_{I} at its input 191, and having an inverter output 192; a first switch 310 having a first-switch first contact 311 and a first-switch second contact 312 and having a first actuator 315 coupled to the inverter 190 input 191; a second switch 320, having a second-switch first contact 321 and a second-switch second contact 322 and having a second actuator 325 coupled to the inverter 190 output 192; a third switch 330, having a third-switch first contact 331 and a third-switch second contact 332 and having a third actuator 335 coupled to the second-switch second contact 322; and a fourth switch 340, having a fourth-switch first contact 341 and a fourth-switch second contact 342 and having a fourth actuator 345 coupled to the third-switch second contact 332 and to the first-switch second contact 312. The first-switch first contact 311 is configured for coupling to the reference potential GND. If the first actuator 315 is actuated by the input signal V_{I}, the first-switch first contact 311 is coupled to the first-switch second contact 312, otherwise the first-switch first contact 311 is decoupled from the first-switch second contact 312. The second-switch first contact 321 is configured for coupling to the reference potential GND. If the second actuator 325 is actuated by the inverter 190 output 192, the second-switch first contact 321 is coupled to the second-switch second contact 322, otherwise the second-switch first contact 321 is decoupled from the second-switch second contact 322. The third-switch first contact 331 is configured for coupling to a supply voltage V_{DD}. If the third actuator 335 is actuated by the second-switch second contact 322, the third-switch first contact 331 is coupled to the third-switch second contact 332, otherwise the third-switch first contact 331 is decoupled from the third-switch second contact 332. The fourth-switch first contact 341 is configured for coupling to the supply voltage V_{DD}, and the fourth-switch second contact 342 is coupled to the second-switch second contact 322. If the fourth actuator 345 is actuated by the first-switch second contact 312, the fourth-switch first contact 341 is coupled to the fourth-switch second contact 342, otherwise the fourth-switch first contact 341 is decoupled from the fourth-switch second contact 342.

The representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

What is claimed is:

1. A digital input buffer, comprising:
a voltage regulator configured for operating in weak inversion and for outputting a regulated potential;
an inverter having as its power source the regulated potential, configured for receiving an input signal at its input, and configured to output an inverter output signal at its output;
a first latch having its input coupled to the inverter input, having an output, and having an enable input; and
a second latch having its input coupled to the inverter output, having an output coupled to the first latch enable input, and having an enable input coupled to the first latch output,
where a first latch output signal from the first latch output coupled to the second latch enable input and a second latch output signal from the second latch output coupled to the first latch enable input enable switching the first latch output signal to the complement of the input signal and enable switching the second latch output signal to that of the input signal.

2. The digital input buffer as recited in claim 1,
wherein if the input signal is a LOGIC LOW, the second latch output signal is a LOGIC LOW and the first latch output signal is a LOGIC HIGH and
wherein if the input signal is a LOGIC HIGH, the second latch output signal is a LOGIC HIGH and the first latch output signal is a LOGIC LOW.

3. The digital input buffer as recited in claim 1,
wherein the first latch comprises: a first field effect transistor (FET) and a third FET,
wherein the first FET has its gate coupled to the first latch input, its drain coupled to the first latch output, and its source configured for coupling to a reference potential,
wherein the third FET has its gate coupled to the first latch enable input, its drain coupled to the first latch output, and its source configured for coupling to a supply voltage,
wherein the first FET is an n-channel, enhancement mode field effect transistor, and
wherein the third FET is a p-channel, enhancement mode field effect transistor.

4. The digital input buffer as recited in claim 3, wherein the substrate of the first FET is configured for coupling to the reference potential and the substrate of the third FET is configured for coupling to the supply voltage.

5. The digital input buffer as recited in claim 1,
wherein the second latch comprises: a second field effect transistor (FET) and a fourth FET,
wherein the second FET has its gate coupled to the second latch input, its drain coupled to the second latch output, and its source configured for coupling to a reference potential,
wherein the fourth FET has its gate coupled to the second latch enable input, its drain coupled to the second latch output, and its source configured for coupling to a supply voltage,
wherein the second FET is an n-channel, enhancement mode field effect transistor, and
wherein the fourth FET is a p-channel, enhancement mode field effect transistor.

6. The digital input buffer as recited in claim 5, wherein the substrate of the second FET is configured for coupling to the reference potential and the substrate of the fourth FET is configured for coupling to the supply voltage.

7. The digital input buffer as recited in claim 1,
wherein the first latch comprises: a first field effect transistor (FET) and a third FET,
wherein the first FET has its gate coupled to the first latch input, its source configured for coupling to a reference potential, and its drain coupled to the first latch output,
wherein the third FET has its gate coupled to the first latch enable input, its drain coupled to the first latch output, and its source configured for coupling to a supply voltage,
wherein the second latch comprises: a second field effect transistor (FET) and a fourth FET,
wherein the second FET has its gate coupled to the second latch input, its source configured for coupling to a reference potential, and its drain coupled to the second latch output,
wherein the fourth FET has its gate coupled to the second latch enable input, its drain coupled to the second latch output, and its source configured for coupling to a supply voltage,
wherein the first FET and the second FET are n-channel, enhancement mode field effect transistors, and
wherein the third FET and the fourth FET are a p-channel, enhancement mode field effect transistors.

8. The digital input buffer as recited in claim 7,
wherein the substrate of the first FET and the substrate of the second FET are configured for coupling to the reference potential and
wherein the substrate of the third FET and the substrate of the fourth FET are configured for coupling to a supply voltage.

9. The digital input buffer as recited in claim 1,
wherein the first latch comprises: a fifth field effect transistor (FET) and a seventh FET,
wherein the fifth FET has its gate coupled to the first latch input, its drain coupled to the first latch output, and its source configured for coupling to a reference potential,
wherein the seventh FET has its gate coupled to the first latch enable input, its drain coupled to the first latch output, and its source configured for coupling to a supply voltage,
wherein the fifth FET is a p-channel, enhancement mode field effect transistor, and
wherein the seventh FET is an n-channel, enhancement mode field effect transistor.

10. The digital input buffer as recited in claim 9, wherein the substrate of the fifth FET is configured for coupling to the reference potential and the substrate of the seventh FET is configured for coupling to the supply voltage.

11. The digital input buffer as recited in claim 1,
wherein the second latch comprises: a sixth field effect transistor (FET) and an eighth FET,
wherein the sixth FET has its gate coupled to the second latch input, its drain coupled to the second latch output, and its source configured for coupling to a reference potential,
wherein the eighth FET has its gate coupled to the second latch enable input, its drain coupled to the second latch output, and its source configured for coupling to a supply voltage,
wherein the sixth FET is a p-channel, enhancement mode field effect transistor, and
wherein the eighth FET is an n-channel, enhancement mode field effect transistor.

12. The digital input buffer as recited in claim 11, wherein the substrate of the sixth FET is configured for coupling to the reference potential and the substrate of the eighth FET is configured for coupling to the supply voltage.

13. The digital input buffer as recited in claim 1,
wherein the first latch comprises: a fifth field effect transistor (FET) and a seventh FET,
wherein the fifth FET has its gate coupled to the first latch input, its source configured for coupling to a reference potential, and its drain coupled to the first latch output,
wherein the seventh FET has its gate coupled to the first latch enable input, its drain coupled to the first latch output, and its source configured for coupling to a supply voltage,
wherein the second latch comprises: a sixth field effect transistor (FET) and an eighth FET,
wherein the sixth FET has its gate coupled to the second latch input, its source configured for coupling to a reference potential, and its drain coupled to the second latch output,
wherein the eighth FET has its gate coupled to the second latch enable input, its drain coupled to the second latch output and its source configured for coupling to a supply voltage,
wherein the fifth FET and the sixth FET are p-channel, enhancement mode field effect transistors, and
wherein the seventh FET and the eighth FET are n-channel, enhancement mode field effect transistors.

14. The digital input buffer as recited in claim 1,
wherein the first latch comprises: a first switch and a third switch,
wherein the first switch has a first-switch first contact configured for coupling to the reference potential, a first-switch second contact coupled to the first latch output, and a first actuator coupled to the first latch input,
wherein if the first actuator is actuated by the input signal, the first-switch first contact is coupled to the first-switch second contact, otherwise the first-switch first contact is decoupled from the first-switch second contact,
wherein the third switch has a third-switch first contact configured for coupling to a supply voltage, a third-switch second contact coupled to the first latch output, and a third actuator coupled to the first latch enable input, and
wherein if the third actuator is actuated by the second latch output signal, the third-switch first contact is coupled to the third-switch second contact, otherwise the third-switch first contact is decoupled from the third-switch second contact.

15. The digital input buffer as recited in claim 14,
wherein the first actuator is actuated by the potential difference between the input signal and the reference potential and
wherein the third actuator is actuated by the potential difference between the supply voltage and the second latch output signal.

16. The digital input buffer as recited in claim 15,
wherein the first switch and/or the third switch are devices selected from the group consisting of relays, vacuum tubes, solid state devices, integrated circuits, single pole single throw relays, single pole double throw relays, triodes, junction transistors, PNP bipolar junction transistors, NPN bipolar junction transistors, junction gate field-effect transistors, n-channel junction gate field-effect transistors, p-channel junction gate field-effect transistors, metal-oxide-semiconductor field effect transistors, n-channel metal-oxide-semiconductor field effect transistors, p-channel metal-oxide-semiconductor field effect transistors, operational amplifiers, and solid state switches.

17. The digital input buffer as recited in claim 1,
wherein the second latch comprises: a second switch and a fourth switch,
wherein the second switch has a second-switch first contact configured for coupling to the reference potential, a second-switch second contact coupled to the second latch output, and a second actuator coupled to the second latch input,
wherein if the second actuator is actuated by the inverter output, the second-switch first contact is coupled to the second-switch second contact, otherwise the second-switch first contact is decoupled from the second-switch second contact,
wherein the fourth switch has a fourth-switch first contact configured for coupling to a supply voltage, a fourth-switch second contact coupled to the second latch output, and a fourth actuator coupled to the second latch enable input, and
wherein if the fourth actuator is actuated by the first latch output signal, the fourth-switch first contact is coupled to the fourth-switch second contact, otherwise the fourth-switch first contact is decoupled from the fourth-switch second contact.

18. The digital input buffer as recited in claim 17,
wherein the second actuator is actuated by the potential difference between that at the inverter output and the reference potential and
wherein the fourth actuator is actuated by the potential difference between the supply voltage and the first latch output signal.

19. The digital input buffer as recited in claim 17,
wherein the second switch and/or the fourth switch are devices selected from the group consisting of relays, vacuum tubes, solid state devices, integrated circuits, single pole single throw relays, single pole double throw relays, triodes, junction transistors, PNP bipolar junction transistors, NPN bipolar junction transistors, junction gate field-effect transistors, n-channel junction gate field-effect transistors, p-channel junction gate field-effect transistors, metal-oxide-semiconductor field effect transistors, n-channel metal-oxide-semiconductor field effect transistors, p-channel metal-oxide-semiconductor field effect transistors, operational amplifiers, and solid state switches.

20. A method, comprising:
adjusting a voltage regulator to operate in weak inversion while outputting a regulated potential;
applying the regulated potential to power an inverter,
where the inverter has its input coupled to an input of a first latch and has its output coupled to an input of a second latch,
where an output of the first latch is coupled to an enable input of the second latch and an output of the second latch is coupled to an enable input of the first latch;
applying an input signal to the inverter input; and
detecting a second latch output signal at the second latch output and/or its complement a first latch output signal at the first latch output.
